(19) United States
(12) Patent Application Publication
(10) Pub. No.: US 2013/0235535 A1
(43) Pub. Date: Sep. 12, 2013

(54) COMPOSITE SUBSTRATE, MODULE, AND COMPOSITE-SUBSTRATE PRODUCTION METHOD

(71) Applicant: MURATA MANUFACTURING CO., LTD., Nagaokakyo-shi (JP)

(72) Inventor: Kazuhiro ISEBO, Nagaokakyo-shi (JP)

(73) Assignee: Murata Manufacturing Co., Ltd., Nagaokakyo-shi (JP)

(21) Appl. No.: 13/870,199

(22) Filed: Apr. 25, 2013

Related U.S. Application Data
(63) Continuation of application No. PCT/JP2011/073399, filed on Oct. 12, 2011.

(30) Foreign Application Priority Data
Oct. 26, 2010 (JP) 2010-239445

(51) Int. Cl. H05K 1/03; H05K 3/00

(52) U.S. Cl. CPC H05K 1/0306; H05K 3/0044
USPC 361/739; 29/849; 174/255

(57) ABSTRACT

A composite substrate includes a ceramic substrate including, on at least one surface, a circuit wire on which an electronic component is to be mounted, a plurality of external connection terminals provided on one surface of the ceramic substrate, and a resin layer provided on the one surface of the ceramic substrate. The external connection terminals have a cross sectional area that decreases with increasing distance from the one surface of the ceramic substrate, and end surfaces of the external connection terminals opposite to end surfaces connected to the ceramic substrate are partially or entirely exposed from the resin layer.

### BACKGROUND OF THE INVENTION

1. Field of the Invention

The present invention relates to a composite substrate including a ceramic substrate including a circuit wire on which electronic components are to be mounted, a module including the composite substrate, and a composite-substrate production method.

2. Description of the Related Art

Japanese Unexamined Patent Application Publication No. 2007-311596 discloses a composite substrate including a ceramic substrate (circuit board) having, on one surface, a circuit wire on which electronic components are to be mounted, and a plurality of external connection terminals (projection electrodes) provided in a peripheral edge portion of the other surface of the ceramic substrate and vertically extending from the other surface. Further, in the composite substrate, a resin layer is provided on the other surface of the ceramic substrate such that at least end surfaces of the plurality of external connection terminals are exposed therefrom. The resin layer is formed by covering the other surface of the ceramic substrate with resin after forming plated layers on the exposed end surfaces of the plurality of external connection terminals. For example, the ceramic substrate is formed of low temperature co-fired ceramic material.

In the composite substrate disclosed in Japanese Unexamined Patent Application Publication No. 2007-311596, since the external connection terminals are columnar or prismatic, the cross-sectional area thereof is constant, and there is a limit on an increase in the cross-sectional area of connecting portions between the external connection terminals and the ceramic substrate. If the cross-sectional area of the connecting portions between the external connection terminals and the ceramic substrate cannot be sufficiently large, stress applied to the external connection terminals, for example, due to a fall cannot be distributed, and sufficient connection strength cannot be ensured between the ceramic substrate and the external connection terminals. This may cause trouble, for example, the external connection terminals may come off the ceramic substrate.

In a composite-substrate production method disclosed in Japanese Unexamined Patent Application Publication No. 2007-311596, after a plurality of external connection terminals are formed in a peripheral edge portion of the other surface of a ceramic substrate, plated layers are formed on exposed end surfaces of the plurality of external connection terminals. For this reason, when the plated layers are formed on the exposed end surfaces of the plurality of external connection terminals, the connection strength between the ceramic substrate and the external connection terminals may be reduced, for example, by entry of plating solution into boundary portions between the ceramic substrate and the external connection terminals.

Further, since the external connection terminals are provided in the peripheral edge portion of the other surface of the ceramic substrate in the composite substrate disclosed in Japanese Unexamined Patent Application Publication No. 2007-311596, the number of external connection terminals that can be formed on the other surface of the ceramic substrate is limited. To ensure a necessary number of external connection terminals, it is necessary to increase the size of the composite substrate itself, and the size of the composite substrate cannot be reduced. Still further, since the external connection terminals are provided in the peripheral edge portion of the other surface of the ceramic substrate, stress applied to the external connection terminals, for example, due to a fall cannot be distributed, and breakage is likely to be caused by concentration of the stress at one or some of the external connection terminals.

### SUMMARY OF THE INVENTION

Preferred embodiments of the present invention provide a composite substrate in which stress applied to external connection terminals, for example, due to a fall is distributed and sufficient connection strength is ensured between a ceramic substrate and the external connection terminals, a module including the composite substrate, and a composite-substrate production method.

A composite substrate according to a preferred embodiment of the present invention includes a ceramic substrate including, on at least one surface, a circuit wire on which an electronic component is to be mounted, a plurality of external connection terminals provided on one surface of the ceramic substrate, and a resin layer provided on the one surface of the ceramic substrate. The external connection terminals have a shape whose cross-sectional area decreases with increasing distance from the one surface of the ceramic substrate, and end surfaces of the external connection terminals opposite to end surfaces connected to the ceramic substrate are partially or entirely exposed from the resin layer.

In the above structure, the external connection terminals preferably have a shape whose cross-sectional area decreases with increasing distance from the one surface of the ceramic substrate, and the end surfaces of the external connection terminals opposite to the end surfaces connected to the ceramic substrate are partially or entirely exposed from the resin layer. Therefore, the cross-sectional area of connecting portions between the external connection terminals and the ceramic substrate can be made larger than in columnar or prismatic external connection terminals having a constant cross-sectional area. Hence, stress applied to the external connection terminals, for example, due to a fall is distributed, and sufficient connection strength is ensured between the ceramic substrate and the external connection terminals. While the ceramic substrate is used as the substrate on which the electronic component is mounted, since the resin layer is provided, even when stress is applied to the composite substrate, for example, due to a fall, deformation of the composite substrate can be prevented. Since sufficient strength is ensured even when the thickness is reduced, the thickness of the composite substrate can be reduced.

In the composite substrate according to preferred embodiments of the present invention, a height of the external connection terminals from the one surface of the ceramic substrate is preferably less than a thickness of the resin layer.

In the above structure, since the height of the external connection terminals from the one surface of the ceramic substrate is less than the thickness of the resin layer, when plated layers are formed on the exposed end surfaces of the external connection terminals, the plated layers can be arranged so as not to protrude from the resin layer, and one surface of the composite substrate where the external connection terminals are provided can be made flat or substantially flat.

In the composite substrate according to a preferred embodiment of the present invention, outer peripheral edges of the end surfaces of the external connection terminals opposite to the end surfaces connected to the ceramic substrate are preferably covered with the resin layer.

In the above structure, since the outer peripheral edges of the end surfaces of the external connection terminals opposite to the end surfaces connected to the ceramic substrate are covered with the resin layer, when plated layers are provided after the resin layer is provided, the connection strength between the ceramic substrate and the external connection terminals is unlikely to be reduced, for example, by entry of plating solution into boundary portions between the ceramic substrate and the external connection terminals.

In the composite substrate according to a preferred embodiment of the present invention, plated layers are preferably provided on the end surfaces of the external connection terminals exposed from the resin layer.

In the above structure, since the plated layers are provided on the end surfaces of the external connection terminals exposed from the resin layer, the exposed end surfaces of the external connection terminals can be protected. Moreover, when the external connection terminals and a mount substrate are connected by solder, connection reliability can be enhanced.

In the composite substrate according to a preferred embodiment of the present invention, the plated layers are preferably arranged so as not to protrude from the resin layer.

In the above structure, since the plated layers are arranged so as not to protrude from the resin layer, one surface of the composite substrate where the external connection terminals are provided can be made flat or substantially flat.

In the composite substrate according to a preferred embodiment of the present invention, the plurality of external connection terminals are preferably arranged in a lattice configuration on the one surface of the ceramic substrate.

In the above structure, since the plurality of external connection terminals are arranged in a lattice configuration on the one surface of the ceramic substrate, as compared with the case in which the external connection terminals are provided in a peripheral edge portion of the one surface of the ceramic substrate, the number of external connection terminals that can be provided on one surface of the ceramic substrate can be increased, and the size of the composite substrate can be reduced while ensuring a necessary number of external connection terminals. Further, since the plurality of external connection terminals are arranged in a lattice configuration without being arranged only in the peripheral edge portion of the one surface of the ceramic substrate, stress applied to the external connection terminals, for example, due to a fall can be distributed, and breakage can be prevented from being caused by concentration of stress at one or some of the external connection terminals.

Next, to achieve the above benefits, a module according to a preferred embodiment of the present invention includes the composite substrate including the above-described structure, and an electronic component mounted on both surfaces of the ceramic substrate or a surface opposite to the surface on which the external connection terminals are provided.

In the above structure, there are provided the composite substrate including the above-described structure, and the electronic component mounted on both surfaces of the ceramic substrate or the surface opposite to the surface on which the external connection terminals are provided. Hence, the cross-sectional area of connecting portions between the ceramic substrate and the external connection terminals can be made larger than in a module including columnar or prismatic external connection terminals having a constant cross-sectional area. Therefore, stress applied to the external connection terminals, for example, due to a fall, can be distributed, and sufficient connection strength can be ensured between the ceramic substrate and the external connection terminals.

Preferably, the module according to a preferred embodiment of the present invention further includes a sealing layer in which the electronic component mounted on the surface opposite to the surface on which the external connection terminals are provided is sealed with resin.

In the above structure, since there is provided the sealing layer in which the electronic component mounted on the surface opposite to the surface on which the external connection terminals are provided is sealed with resin, it is possible to protect the electronic component mounted on the surface opposite to the surface on which the external connection terminals are provided and to significantly reduce or prevent warping of the module.

Next, to achieve the above benefits, a composite-substrate production method according to a preferred embodiment of the present invention includes a first step of forming, in a resin sheet, a plurality of holes whose aperture area is smaller on one side than on the other side and filling the plurality of holes with a conductive material, a second step of stacking a plurality of the resin sheets on one surface of an unfired ceramic substrate including, on at least one surface, a circuit wire on which an electronic component is to be mounted so that the aperture area of the plurality of holes successively decreases, and firing the resin sheets to form a plurality of external connection terminals having a shape whose cross-sectional area decreases with increasing distance from the one surface of the fired ceramic substrate, and a third step of forming a resin layer on the one surface of the ceramic substrate so that end surfaces of the external connection terminals opposite to end surfaces connected to the ceramic substrate are exposed partially or entirely.

In the above structure, a plurality of holes whose aperture area is smaller on one side than on the other side are arranged in the resin sheet, and the plurality of holes are filled with the conductive material. On one surface of the unfired ceramic substrate including, on at least one surface, the circuit wire on which the electronic component is to be mounted, a plurality of the resin sheets are stacked so that the aperture area of the plurality of holes successively decreases, and are fired to define a plurality of external connection terminals having a shape whose cross-sectional area decreases with increasing distance from the one surface of the fired ceramic substrate. The resin layer is arranged on the one surface of the ceramic substrate so that the end surfaces of the external connection terminals opposite to the end surfaces connected to the ceramic substrate are exposed partially or entirely. Hence, the cross-sectional area of connecting portions to the ceramic substrate can be made larger than in a module including columnar or prismatic external connection terminals having a constant cross-sectional area. Therefore, stress applied to the external connection terminals, for example, due to a fall can be distributed, and it is possible to produce a composite substrate in which sufficient connection strength is ensured between a ceramic substrate and external connection terminals.

Next, to achieve the above benefits, a composite-substrate production method according to a preferred embodiment of the present invention includes a first step of screen-printing a conductive material a plurality of times on one surface of an unfired ceramic substrate including, on at least one surface, a circuit wire on which an electronic component is to be mounted so as to form a plurality of unfired external connection terminals having a shape whose cross-sectional area decreases with increasing distance from the one surface of the ceramic substrate, a second step of firing the ceramic substrate on which the plurality of unfired external connection terminals are arranged, and a third step of forming a resin layer on the one surface of the ceramic substrate so that end surfaces of the external connection terminals opposite to end surfaces connected to the ceramic substrate are exposed partially or entirely.

In the above structure, the conductive material is screen-printed a plurality of times on one surface of the unfired ceramic substrate including, on at least one surface, the circuit wire on which the electronic component is to be mounted so as to define a plurality of unfired external connection terminals having a shape whose cross-sectional area decreases with increasing distance from the one surface of the ceramic substrate. The ceramic substrate on which the plurality of unfired external connection terminals are arranged is fired, and the resin layer is formed on the one surface of the ceramic substrate so that the end surfaces of the external connection terminals opposite to the end surfaces connected to the ceramic substrate are exposed partially or entirely. Thus, the cross-sectional area of connecting portions to the ceramic substrate can be made larger than in columnar or prismatic external connection terminals having a constant cross-sectional area. Hence, stress applied to the external connection terminals, for example, due to a fall can be distributed, and it is possible to produce a composite substrate in which sufficient connection strength is ensured between a ceramic substrate and external connection terminals.

Next, to achieve the above benefits, a composite-substrate production method includes a first step of forming, in an unfired ceramic sheet, a plurality of holes whose aperture area is smaller on one side than on the other side and filling the plurality of holes with a conductive material, a second step of stacking a plurality of the ceramic sheets on one surface of an unfired ceramic substrate having a sintering temperature lower than that of the ceramic sheets and including, on at least one surface, a circuit wire on which an electronic component is to be mounted so that the aperture area of the holes successively unsintered ceramic sheets to form a plurality of external connection terminals having a shape whose cross-sectional area decreases with increasing distance from the one surface of the ceramic substrate, and a third step of forming a resin layer on the one surface of the ceramic substrate so that end surfaces of the external connection terminals opposite to end surfaces connected to the ceramic substrate are exposed partially or entirely.

In the above structure, a plurality of holes whose aperture area is smaller on one side than on the other side are arranged in the unfired ceramic sheet, and the plurality of holes are filled with the conductive material. A plurality of the ceramic sheets are stacked on one surface of the unfired ceramic substrate having a sintering temperature lower than that of the plurality of ceramic sheets and including, on at least one surface, the circuit wire on which the electronic component is to be mounted so that the aperture area of the plurality of holes successively decreases, and are fired, and the unsintered ceramic sheets are removed to form a plurality of external connection terminals having a shape whose cross-sectional area decreases with increasing distance from the one surface of the ceramic substrate. Since the resin layer is arranged on the one surface of the ceramic substrate so that the end surfaces of the external connection terminals opposite to the end surfaces connected to the ceramic substrate are partially or entirely exposed, the cross-sectional area of connecting portions to the ceramic substrate can be made larger than in columnar or prismatic external connection terminals having a constant cross-sectional area. Hence, stress applied to the external connection terminals, for example, due to a fall can be distributed, and it is possible to produce a composite substrate in which sufficient connection strength is ensured between a ceramic substrate and external connection terminals. Further, since the unfired ceramic sheets significantly reduce or prevent shrinkage of the ceramic substrate during firing, a composite substrate with high dimensional accuracy can be produced.

In the composite-substrate production method according to a preferred embodiment of the present invention, preferably, the ceramic substrate preferably is a ceramic multilayer substrate formed by stacking a plurality of ceramic layers.

In the above structure, since the ceramic substrate is a ceramic multilayer substrate defined by stacking a plurality of ceramic layers, it is possible to produce a composite substrate including a ceramic substrate including a complicated circuit wire.

In the composite-substrate production method according to a preferred embodiment of the present invention, preferably, in the third step, the end surfaces of the external connection terminals opposite to the end surfaces connected to the ceramic substrate are partially or entirely exposed by grinding a surface of the formed resin layer.

In the above structure, since the end surfaces of the external connection terminals opposite to the end surfaces connected to the ceramic substrate are partially or entirely exposed by grinding the surface of the resin layer, the height of the external connection terminals from the one surface of the ceramic substrate can be easily adjusted by grinding the external connection terminals together with the resin layer. This allows one surface of the composite substrate where the external connection terminals are provided to be made flat or substantially flat.

In the composite-substrate production method according to a preferred embodiment of the present invention, preferably, in the third step, the resin layer is formed so that a thickness of the resin layer is more than a height of the external connection terminals from the one surface of the ceramic substrate.

In the above structure, since the resin layer is provided so that the thickness thereof is more than the height of the external connection terminals from the one surface of the ceramic substrate, when plated layers are provided on the exposed end surfaces of the external connection terminals, the plated layers can be arranged so as not to protrude from the resin layer.

In the composite-substrate production method according to a preferred embodiment of the present invention, preferably, in the third step, the resin layer is formed to cover outer peripheral edges of the end surfaces of the external connection terminals opposite to the end surfaces connected to the ceramic substrate.

In the above structure, since the resin layer is arranged to cover the outer peripheral edges of the end surfaces of the external connection terminals opposite to the end surfaces connected to the ceramic substrate, when the plated layers are provided on the exposed end surfaces of the external connection terminals after the resin layer is formed, the connection strength between the ceramic substrate and the external connection terminals is unlikely to be reduced, for example, by entry of plating solution into boundary portions between the ceramic substrate and the external connection terminals.

In the composite-substrate production method according to a preferred embodiment of the present invention, preferably, in the third step, plated layers are arranged on the end surfaces of the external connection terminals exposed from the resin layer so as not to protrude from the resin layer.

In the above structure, since the plated layers are arranged on the end surfaces of the external connection terminals exposed from the resin layer so as not to protrude from the resin layer, the exposed end surfaces of the external connection terminals can be protected. Moreover, when the external connection terminals are connected to a mount substrate by solder, connection reliability can be enhanced. Further, since the plated layers are provided after the resin layer is provided, solder wettability is not reduced by seepage of a resin component from the resin layer onto the end surfaces of the external connection terminals on which the plated layers are arranged, and this can enhance connection reliability. Still further, one surface of the composite substrate where the external connection terminals are provided can be made flat or substantially flat.

According to the above structure, the external connection terminals have a shape whose cross-sectional area decreases with increasing distance from one surface of the ceramic substrate, and the end surfaces of the external connection terminals opposite to the end surfaces connected to the ceramic substrate are partially or entirely exposed from the resin layer. Hence, the cross-sectional area of the connecting portions between the external connection terminals and the ceramic substrate can be made larger than in columnar or prismatic external connection terminals having a constant cross-sectional area. Therefore, stress applied to the external connection terminals, for example, due to a fall can be distributed, and sufficient connection strength can be ensured between the ceramic substrate and the external connection terminals. Further, while the ceramic substrate is used as the substrate on which the electronic component is mounted, since the resin layer is provided, deformation of the composite substrate can be prevented even when stress is applied to the composite substrate, for example, by a fall, and sufficient strength can be ensured even when the thickness is reduced. Therefore, the thickness of the composite substrate can be reduced.

Since the composite substrate including the above structure and the electronic component mounted on both surfaces of the ceramic substrate or the surface opposite to the surface where the external connection terminals are provided are provided, the cross-sectional area of connecting portions between the ceramic substrate and the external connection terminals can be made larger than in a module including a composite substrate in which columnar or prismatic external connection terminals having a constant cross-sectional area are provided. Hence, stress applied to the external connection terminals, for example, due to a fall can be distributed, and sufficient connection strength can be ensured between the ceramic substrate and the external connection terminals.

Further, according to the above structure, a plurality of holes whose aperture area is smaller on one side than on the other side are provided in the resin sheet, and the plurality of holes are filled with the conductive material. A plurality of resin sheets are stacked on one surface of the unfired ceramic substrate including, on at least one surface, the circuit wire on which the electronic component is to be mounted so that the aperture area of the holes successively decreases, and are fired to define the plurality of external connection terminals having a shape whose cross-sectional area decreases with increasing distance from the one surface of the fired ceramic substrate. The resin layer is arranged on the one surface of the ceramic substrate so that the end surfaces of the external connection terminals opposite to the end surfaces connected to the ceramic substrate are exposed partially or entirely. Thus, the cross-sectional area of the connecting portions to the ceramic substrate can be made larger than in columnar or prismatic external connection terminals having a constant cross-sectional area. Therefore, stress applied to the external connection terminals, for example, due to a fall can be distributed, and it is possible to produce a composite substrate in which sufficient connection strength is ensured between a ceramic substrate and external connection terminals.

According to the above structure, the conductive material is screen-printed a plurality of times on one surface of the unfired ceramic substrate including, on at least one surface, the circuit wire on which the electronic component is to be mounted so as to define a plurality of unfired external connection terminals having a shape whose cross-sectional area decreases with increasing distance from the one surface of the ceramic substrate. The ceramic substrate on which the plurality of unfired external connection terminals are provided is fired, and the resin layer is arranged on the one surface of the ceramic substrate so that the end surfaces of the external connection terminals opposite to the end surfaces connected to the ceramic substrate are exposed partially or entirely. Since the cross-sectional area of connecting portions connected to the ceramic substrate can be made larger than in columnar or prismatic external connection terminals having a constant cross-sectional area, stress applied to the external connection terminals, for example, due to a fall can be distributed. Thus, it is possible to produce a composite substrate in which sufficient connection strength is ensured between a ceramic substrate and external connection terminals.

Further, according to the above structure, a plurality of holes whose aperture area is smaller on one side than on the other side are provided in the unfired ceramic sheet, and the plurality of holes are filled with the conductive material. A plurality of ceramic sheets are stacked on one surface of the unfired ceramic substrate having a sintering temperature lower than that of the ceramic sheets and having, on at least one surface, the circuit wire on which the electronic component is to be mounted so that the aperture area of the plurality of holes successively decreases, and are fired, and the unsintered ceramic sheets are removed to define a plurality of external connection terminals having a shape whose cross-sectional area decreases with increasing distance from the one surface of the ceramic substrate. Since the resin layer is arranged on the one surface of the ceramic substrate so that the end surfaces of the external connection terminals opposite to the end surfaces connected to the ceramic substrate are exposed partially or entirely, the cross-sectional area of the connecting portions to the ceramic substrate can be made larger than in columnar or prismatic external connection terminals having a constant cross-sectional area. Hence, stress applied to the external connection terminals, for example, due to a fall can be distributed, and it is possible to produce a composite substrate in which sufficient connection strength is ensured between a ceramic substrate and external connection terminals. Further, since the unfired ceramic sheets significantly reduce or prevent shrinkage of the ceramic substrate during firing, a composite substrate with high dimensional accuracy can be produced.

The above and other elements, features, steps, characteristics and advantages of the present invention will become more apparent from the following detailed description of the preferred embodiments with reference to the attached drawings.

### BRIEF DESCRIPTION OF THE DRAWINGS

FIG. 1 is a schematic view illustrating a structure of a module according to a first preferred embodiment of the present invention.

FIG. 2 is a plan view illustrating a structure of a side of the module of the first preferred embodiment of the present invention on which external connection terminals are provided.

FIGS. 3A to 3F include schematic views illustrating a composite-substrate production procedure according to the first preferred embodiment of the present invention.

FIGS. 4A to 4E include schematic views illustrating another composite-substrate production procedure according to the first preferred embodiment of the present invention.

FIGS. 5A to 5C include schematic views illustrating a further composite-substrate production procedure according to the first preferred embodiment of the present invention.

FIGS. 6A and 6B include schematic views illustrating a structure of a module according to a second preferred embodiment of the present invention.

FIG. 7 is a plan view illustrating structures of one external connection terminal and its surroundings in the module according to the second preferred embodiment of the present invention.

FIG. 8 is a schematic view illustrating a module in which an electronic component is mounted on a portion of one surface of a ceramic substrate where external connection terminals are not provided.

### DETAILED DESCRIPTION OF THE PREFERRED EMBODIMENTS

Preferred embodiments of the present invention will be described in detail below with reference to the drawings.

### First Preferred Embodiment

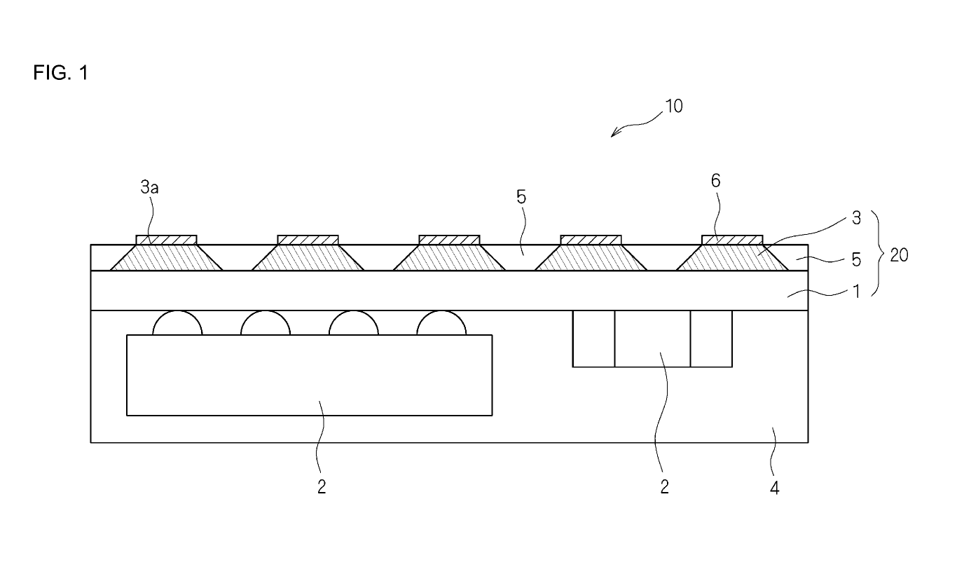

FIG. 1 is a schematic view illustrating a structure of a module according to a first preferred embodiment of the present invention. As illustrated in FIG. 1, a module 10 preferably includes a ceramic substrate 1, a plurality of external connection terminals 3 provided on one surface of the ceramic substrate 1, a plurality of electronic components 2 mounted on a surface of the ceramic substrate 1 opposite to the surface with the external connection terminals 3, a sealing layer 4 in which the electronic components 2 mounted on the surface of the ceramic substrate 1 opposite to the surface with the external connection terminals 3 are sealed with resin, and a resin layer 5 that covers the one surface of the ceramic substrate 1 with the plurality of external connection terminals 3. The ceramic substrate 1, the external connection terminals 3, and the resin layer 5 define a composite substrate 20.

As the ceramic substrate 1, for example, an LTCC (Low Temperature Co-fired Ceramic) substrate is preferably used. The ceramic substrate 1 may be a ceramic single-layer substrate defined by one ceramic layer, or a ceramic multilayer substrate defined by a plurality of stacked ceramic layers. On at least one surface of the ceramic substrate 1, a circuit wire (not illustrated) on which the electronic components 2 are mounted is preferably provided. The electronic components 2 are surface mount electronic components (surface mount devices) that can be surface-mounted on the ceramic substrate 1. While the ceramic substrate 1 is used as the substrate on which the electronic components 2 are mounted, since the resin layer 5 is provided, even when stress is applied to the composite substrate 20, for example, due to a fall, deformation of the composite substrate 20 is prevented. Since sufficient strength is ensured even when the thickness is reduced, the thickness of the composite substrate 20 can be reduced.

The external connection terminals 3 preferably have a shape whose cross-sectional area decreases with increasing distance from one surface of the ceramic substrate 1, for example, a substantially truncated conical shape or a substantially truncated pyramidal shape. Since the cross-sectional area of connecting portions to the ceramic substrate 1 can be made larger in the external connection terminals 3 than in columnar or prismatic external connection terminals having a constant cross-sectional area, stress applied to the external connection terminals 3, for example, due to a fall can be distributed, and sufficient connection strength is ensured between the ceramic substrate 1 and the external connection terminals 3. The cross sections of the external connection terminals 3 may have a circular shape, a rectangular shape, other polygonal shapes, etc. End surfaces of the external connection terminals 3 opposite to end surfaces connected to the ceramic substrate 1 are preferably partially or entirely exposed from the resin layer 5. The exposed end surfaces 3a of the external connection terminals 3 are provided with plated layers 6. The external connection terminals 3 provided with the plated layers 6 are connected to a mount substrate (for example, a motherboard) by solder. For example, the plated layers 6 are preferably defined by a film deposition of Ni/Sn or Ni/Au formed using wet plating.

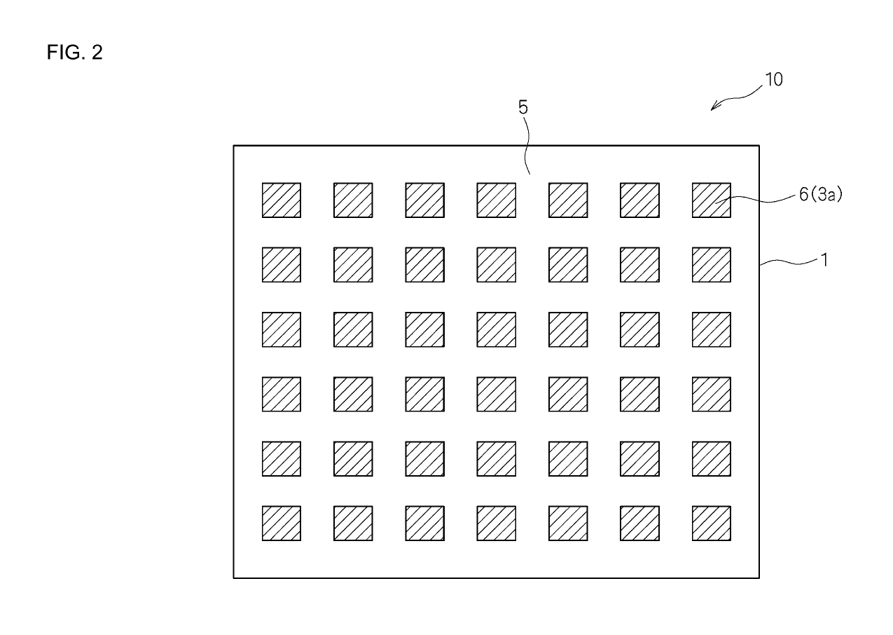

FIG. 2 is a plan view illustrating a structure of a side of the module 10 of the first preferred embodiment of the present invention where the external connection terminals 3 are provided. As illustrated in FIG. 2, the plurality of external connection terminals 3 are preferably not provided in a peripheral edge portion of one surface of the ceramic substrate 1, but are arranged in a lattice configuration on the one surface of the ceramic substrate 1. In this preferred embodiment, the external connection terminals 3 have a substantially truncated pyramidal shape. Hence, the end surfaces 3a exposed from the resin layer 5 are rectangular, and the plated layers 6 are provided on the exposed end surfaces 3a.

Since the plurality of external connection terminals 3 are arranged in a lattice configuration on one surface of the ceramic substrate 1, compared with a case in which the external connection terminals are provided in a peripheral edge portion of one surface of the ceramic substrate 1, the number of external connection terminals 3 that can be formed on the one surface of the ceramic substrate 1 can be increased, and the size of the module 10 (composite substrate 20) can be reduced while ensuring a necessary number of external connection terminals 3. Further, since the plurality of external connection terminals 3 are preferably arranged in a lattice configuration without being provided only in the peripheral edge portion of one surface of the ceramic substrate 1, stress applied to the external connection terminals 3, for example, due to a fall can be distributed, and breakage can be prevented from being caused by concentration of the stress at one or some of the external connection terminals 3. Still further, since a large number of external connection terminals 3 can be provided on one surface of the ceramic substrate 1, it is possible to efficiently exhaust heat generated by the electronic components 2 that are mounted on the surface of the ceramic substrate 1 opposite to the surface where the external connection terminals 3 are provided.

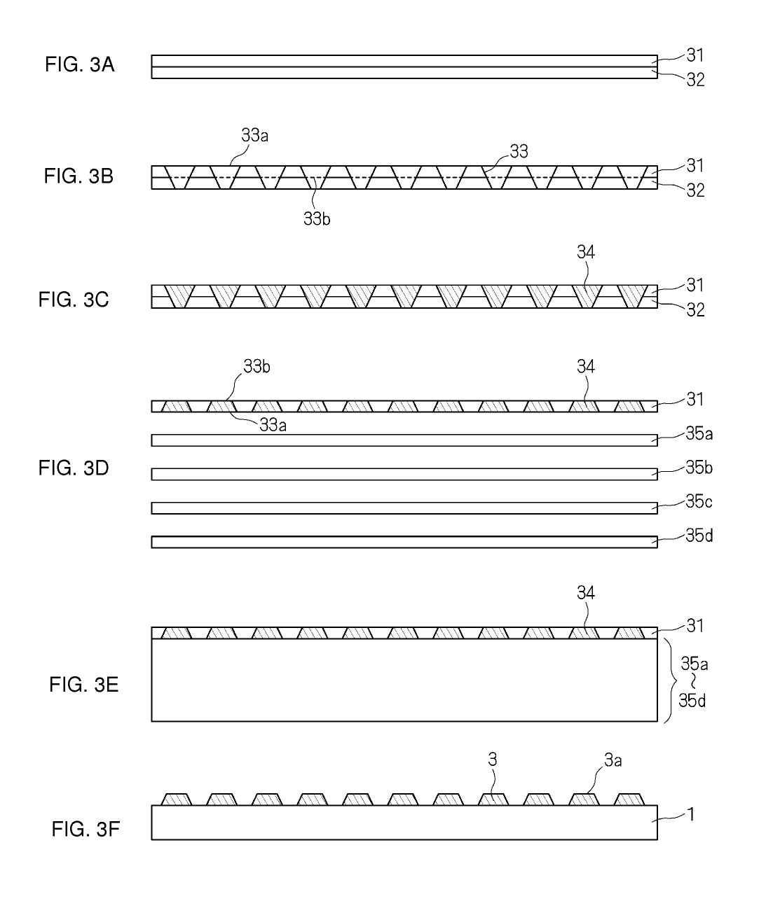

FIGS. 3A to 3F include schematic views illustrating a production procedure for the composite substrate 20 according to the first preferred embodiment of the present invention. First, as illustrated in FIG. 3A, a resin sheet 31 made of a material that is burnt down in a firing step, such as, for example, polypropylene or acrylic, is prepared. When the use of only the resin sheet 31 makes the shape unstable, a base material 32 made of a material harder than the resin sheet 31 is preferably stuck on the resin sheet 31.

As illustrated in FIG. 3B, a plurality of holes 33 are formed in a lattice configuration in the resin sheet 31 by using, for example, laser light, a die, etc. The holes 33 are preferably tapered to narrow from the resin sheet 31 toward the base material 32. The holes 33 are shaped like a substantially truncated cone such that the area of apertures 33b of the holes 33 (aperture area on one side) is smaller than the area of apertures 33a on a side of the resin sheet 31 opposite to the base material 32 (aperture area on the other side). Since the base material 32 is stuck on the resin sheet 31, it has substantially truncated conical holes continuing from the holes 33.

As illustrated in FIG. 3C, the holes 33 provided in the resin sheet 31 are preferably filled with a conductive material 34 containing, for example, Ag, Cu, Pd, and a compound including at least one of these. Since the base material 32 is stuck on the resin sheet 31, the substantially truncated conical holes continuing from the holes 33 are also filled with the conductive material 34.

As illustrated in FIG. 3D, the resin sheet 31 with the holes 33 filled with the conductive material 34 and a plurality of ceramic green sheets 35a to 35d including circuit wires (not illustrated) are prepared. The resin sheet 31 is provided in a state separated from the base material 32 and is turned upside down. The plurality of ceramic green sheets 35a to 35d are preferably produced by a conventional method. For example, a ceramic green sheet having a thickness of about 10 μm to about 200 μm is preferably produced by coating a PET film with ceramic slurry and then drying the ceramic slurry.

As illustrated in FIG. 3E, the resin sheet 31 and the plurality of ceramic green sheets 35a to 35d are stacked. When the resin sheet 31 is stacked on the ceramic green sheet 35a, it is preferably stacked such that a surface thereof having the apertures 33a of the holes 33 having a larger aperture area comes into contact with the ceramic green sheet 35a. For example, the resin sheet 31 and the plurality of ceramic green sheets 35a to 35d thus stacked are pressure-bonded with a pressure of about 100 kg/cm² to about 1500 kg/cm² and at a temperature of about 40° C. to about 100° C. Here, the stacked ceramic green sheets 35a to 35d define an unfired ceramic substrate. The ceramic green sheets 35a to 35d are not limited to a plurality of stacked sheets, and may alternatively be replaced with one sheet if so desired.

As illustrated in FIG. 3F, the resin sheet 31 and the plurality of ceramic green sheets 35a to 35d are fired in a stacked state. By firing the resin sheet 31 and the plurality of ceramic green sheets 35a to 35d in the stacked state, a ceramic substrate 1 is formed. By firing, the resin sheet 31 is burnt down, and a plurality of substantially truncated conical external connection terminals 3, whose cross-sectional area decreases with increasing distance from one surface of the ceramic substrate 1, are formed on the one surface of the ceramic substrate 1. Firing is performed at about 850° C. in air when the conductive material 34 is composed mostly of Ag, and at about 950° C. in a reductive atmosphere when the conductive material 34 is composed mostly of Cu, for example.

After that, a composite substrate 20 illustrated in FIG. 1 can be produced by arranging a resin layer 5 on the one surface of the ceramic substrate 1 on which the plurality of external connection terminals 3 are provided. As an exemplary method of forming the resin layer 5, resin is applied to cover the one surface of the ceramic substrate 1 having the plurality of external connection terminals 3, and is set under a predetermined condition to form a resin layer 5. Further, a surface of the formed resin layer 5 is ground to partially or entirely expose end surfaces of the external connection terminals 3 opposite to end surfaces connected to the ceramic substrate 1. Alternatively, for example, in a state in which the end surfaces of the external connection terminals 3 opposite to the end surfaces connected to the ceramic substrate 1 are partially or entirely exposed, resin is filled between the plurality of external connection terminals 3 by screen printing and is set to provide a resin layer 5. The resin material used for the resin layer 5 is preferably a thermosetting resin such as, for example, epoxy resin.

Further, since plated layers 6 are arranged on the exposed end surfaces 3a of the external connection terminals 3 after the resin layer 5 is provided on the one surface of the ceramic substrate 1 in the composite substrate 20, when the plated layers 6 are arranged, boundary portions between the ceramic substrate 1 and the external connection terminals 3 are covered with the resin layer 5. Thus, for example, plating solution is unlikely to enter the boundary portions, and this reduces the influence of plating. For this reason, in the composite substrate 20, the connection strength between the ceramic substrate 1 and the external connection terminals 3 is unlikely to decrease.

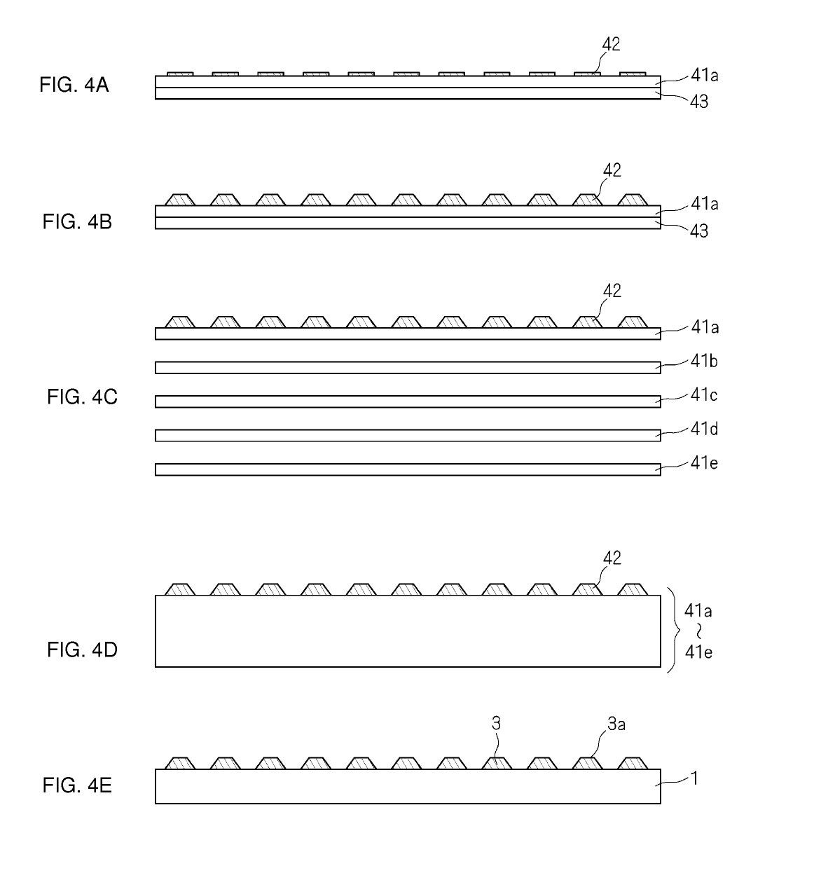

The method for producing the composite substrate 20 is not limited to the method illustrated in FIG. 3A to 3F. For example, FIGS. 4A to 4E include schematic views illustrating another production procedure for the composite substrate 20 of the first preferred embodiment of the present invention. First, as illustrated in FIG. 4A, a conductive material 42 is preferably screen-printed in a lattice configuration on one surface of a ceramic green sheet 41a after firing. When the use of only the ceramic green sheet 41a makes the shape unstable, a base material 43 harder than the ceramic green sheet 41a is stuck onto the ceramic green sheet 41a. The conductive material 42 preferably contains, for example, Ag, Cu, Pd, and a compound including at least one of these.

Next, as illustrated in FIG. 4B, the conductive material 42 is preferably screen-printed on the one surface of the ceramic green sheet 41a a plurality of times such that a plurality of unfired external connection terminals having a substantially truncated conical shape, whose cross-sectional area decreases with increasing distance from the one surface of the ceramic green sheet 41a, are formed on the one surface of the ceramic green sheet 41a. By using a plurality of screen printing plates that are different in size of an aperture portion, the external connection terminals 3 having the above-described shape can be provided.

Then, as illustrated in FIG. 4C, the ceramic green sheet 41a including the one surface on which the plurality of unfired truncated conical external connection terminals are provided, and a plurality of ceramic green sheets 41b to 41e having circuit wires (not illustrated) are prepared. The ceramic green sheet 41a is separated from the base material 43.

Further, as illustrated in FIG. 4D, the plurality of ceramic green sheets 41a to 41e are stacked. When the ceramic green sheet 41a is stacked on the ceramic green sheet 41b, the ceramic green sheet 41a including the unfired external connection terminals is stacked on the ceramic green sheet 41b. For example, the plurality of stacked ceramic green sheets 41a to 41e are preferably pressure-bonded with a pressure of about 100 kg/cm² to about 1500 kg/cm² and at a temperature of about 40° C. to about 100° C. Here, the plurality of stacked ceramic green sheets 41a to 41e define an unfired ceramic substrate. Further, the ceramic green sheets 41a to 41e are not limited to a plurality of stacked sheets, and may alternatively be replaced with one sheet if so desired.

Then, as illustrated in FIG. 4E, the plurality of ceramic green sheets 41a to 41e are fired in a stacked state. By firing the plurality of ceramic green sheets 41a to 41e in the stacked state, a ceramic substrate 1 is formed. By firing, a plurality of substantially truncated conical external connection terminals 3, whose cross-sectional area decreases with increasing distance from one surface of the ceramic substrate 1, are defined on the one surface of the ceramic substrate 1. After that, a resin layer 5 is arranged on the one surface of the ceramic substrate 1 with the plurality of external connection terminals 3 so that end surfaces of the external connection terminals 3 opposite to end surfaces connected to the ceramic substrate 1 are partially or entirely exposed, whereby a composite substrate 20 illustrated in FIG. 1 can be produced.

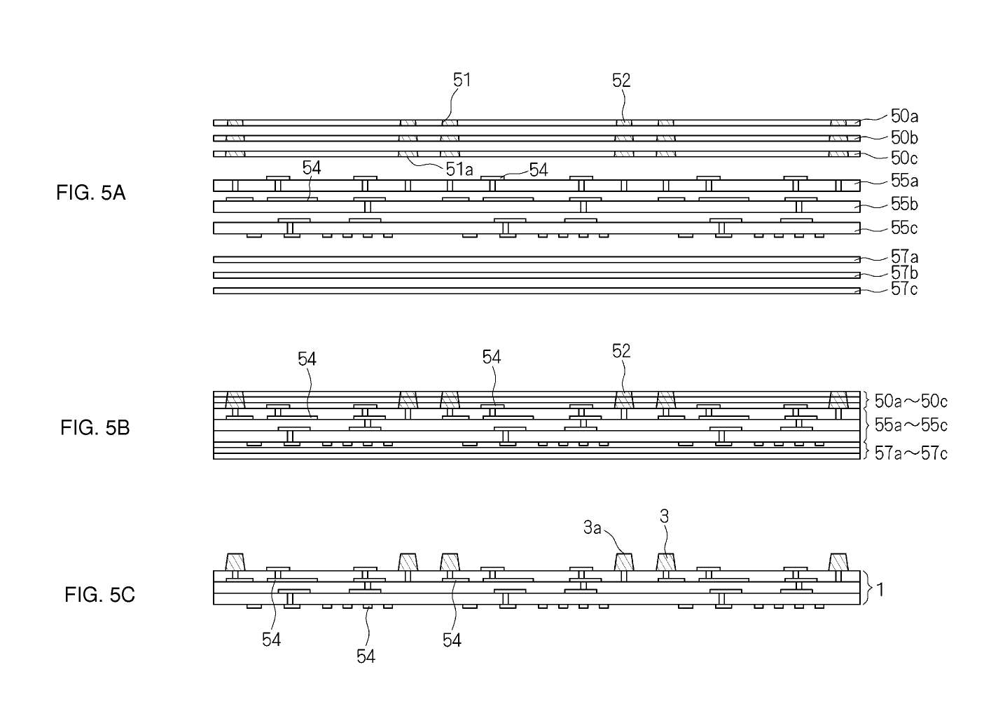

FIGS. 5A to 5C include schematic views illustrating a further production procedure for the composite substrate 20 of the first preferred embodiment of the present invention. First, as illustrated in FIG. 5A, a plurality of shrinkage-suppressing ceramic green sheets (ceramic sheets) 50a to 50c containing a sintering-resistant ceramic material, which is not sintered at a firing temperature of a low temperature co-fired ceramic material, as a main component are prepared. As powder containing the sintering-resistant ceramic material as a main component, alumina powder is preferably used as an example. By dispersing the alumina powder in an organic vehicle to prepare slurry and shaping the prepared slurry into a sheet by casting, shrinkage-suppressing ceramic green sheets 50a to 50c are produced. The sintering temperature of the shrinkage-suppressing ceramic green sheets 50a to 50c is preferably about 1500° C. to about 1600° C., which is much higher than the sintering temperature of a ceramic green sheet made of a low-temperature co-fired ceramic material (for example, about 900° C.) Hence, the shrinkage-suppressing ceramic green sheets 50a to 50c are substantially not sintered at the firing temperature of the ceramic green sheet made of a low-temperature co-fired ceramic material. As the powder containing a sintering-resistant ceramic material as a main component, besides alumina, for example, powder of zirconia or magnesia can be used.

A plurality of holes 51 are preferably formed in a lattice configuration in the shrinkage-suppressing ceramic green sheets 50a to 50c by using laser light, a die, etc. Since the plurality of shrinkage-suppressing ceramic green sheets 50a to 50c are used in a stacked state, the holes 51 whose aperture area successively increases from the shrinkage-suppressing ceramic green sheet 50a to the shrinkage-suppressing ceramic green sheet 50c, take a continuous and substantially truncated conical shape when the shrinkage-suppressing ceramic green sheets 50a to 50c are stacked. The holes 51 defined in the shrinkage-suppressing ceramic green sheets 50a to 50c, whose aperture area successively increases, are filled with a conductive material 52 preferably containing, for example, Ag, Cu, Pd, and a compound including at least one of these.

Further, a plurality of ceramic green sheets 55a to 55c on which circuit wires 54 are provided and a plurality of shrinkage-suppressing ceramic green sheets 57a to 57c including no hole are prepared. Preferably, the shrinkage-suppressing ceramic green sheets 50a to 50c and 57a to 57c contain a component common to a ceramic component contained in the ceramic green sheets 55a to 55c.

Next, as illustrated in FIG. 5B, the plurality of shrinkage-suppressing ceramic green sheets 50a to 50c, the plurality of ceramic green sheets 55a to 55c, and the plurality of shrinkage-suppressing ceramic green sheets 57a to 57c are stacked. When the shrinkage-suppressing ceramic green sheets 50a to 50c are stacked on the ceramic green sheet 55a, they are stacked so that the shrinkage-suppressing ceramic green sheet 50c with apertures 51a of the holes 51 having the largest aperture area comes into contact with the ceramic green sheet 55a. For example, the plurality of shrinkage-suppressing ceramic green sheets 50a to 50c, the plurality of ceramic green sheets 55a to 55c, and the plurality of shrinkage-suppressing ceramic green sheets 57a to 57c thus stacked are pressure-bonded with a pressure of about 100 kg/cm² to about 1500 kg/cm² and at a temperature of 40° C. to 100° C. Here, the plurality of stacked ceramic green sheets 55a to 55c define an unfired ceramic substrate. Further, the shrinkage-suppressing ceramic green sheets 50a to 50c, the ceramic green sheets 55a to 55c, and the shrinkage-suppressing ceramic green sheets 57a to 57c are each not limited to a plurality of stacked sheets, and may alternatively be replaced with one sheet if so desired.

Then, as illustrated in FIG. 5C, the plurality of shrinkage-suppressing ceramic green sheets 50a to 50c, the plurality of ceramic green sheets 55a to 55c, and the plurality of shrinkage-suppressing ceramic green sheets 57a to 57c are fired in a stacked state. By firing the plurality of stacked ceramic green sheets 55a to 55c, a ceramic substrate 1 is provided. However, at the firing temperature of the ceramic green sheets 55a to 55c (for example, about 900° C.), the shrinkage-suppressing ceramic green sheets 50a to 50c and 57a to 57c having a sintering temperature of about 1500° C. to about 1600° C., which is much higher, are not sintered, and do not shrink in the planar direction, but shrink only in the height direction. Hence, a plurality of substantially truncated conical external connection terminals 3, whose cross-sectional area decreases with increasing distance from one surface of the ceramic substrate 1, are formed on the one surface of the ceramic substrate 1.

When firing is performed at the temperature at which the shrinkage-suppressing ceramic green sheets 50a to 50c and 57a to 57c are not sintered, organic vehicles contained in the shrinkage-suppressing ceramic green sheets 50a to 50c and 57a to 57c are burnt into an aggregate of alumina powder. The aggregate of alumina powder can be easily removed, for example, by blasting. By removing the aggregate of alumina powder (unsintered shrinkage-suppressing ceramic green sheets 50a to 50c and 57a to 57c), a plurality of substantially truncated conical external connection terminals 3 are defined. By forming a resin layer 5 on the one surface of the ceramic substrate 1 on which the plurality of external connection terminals 3 are provided, a composite substrate 20 illustrated in FIG. 1 can be produced. While the shrinkage-suppressing ceramic green sheets 57a to 57c are stacked on the surface of the ceramic substrate 1 on which the external connection terminals 3 are not formed in the production method of the first preferred embodiment, the ceramic substrate 1 may be formed without using these sheets.

As described above, in the composite substrate 20 of the first preferred embodiment, the external connection terminals 3 provided on one surface of the ceramic substrate have a shape whose cross-sectional area decreases with increasing distance from the one surface of the ceramic substrate 1 (a substantially truncated conical shape), and the end surfaces of the external connection terminals 3 opposite to the end surfaces connected to the ceramic substrate 1 are exposed partially or entirely. Hence, the cross-sectional area of the connecting portions between the external connection terminals 3 and the ceramic substrate 1 can be made larger than in columnar or prismatic external connection terminals having a constant cross-sectional area, and stress applied to the external connection terminals 3, for example, due to a fall can be distributed. This ensures sufficient connection strength between the ceramic substrate 1 and the external connection terminals 3. Further, while the ceramic substrate 1 is used as the substrate on which the electronic components 2 are mounted, since the resin layer 5 is provided, deformation of the composite substrate can be prevented even when stress is applied to the composite substrate 20, for example, due to a fall, and sufficient strength can be ensured even when the thickness is reduced. Thus, the thickness of the composite substrate can be reduced. Further, the height of the external connection terminals 3 from the one surface of the ceramic substrate 1 (for example, about 10 μm) can be easily adjusted by grinding the external connection terminals 3 together with the surface of the resin layer 5, and one surface of the composite substrate 20 on which the external connection terminals 3 are provided can be made flat or substantially flat.

Since the module 10 includes the composite substrate 20 and the electronic components 2 mounted on both surfaces of the ceramic substrate 1 or the surface of the ceramic substrate 1 opposite to the surface on which the external connection terminals 3 are provided, the cross-sectional area of the connecting portions between the ceramic substrate 1 and the external connection terminals 3 can be made larger than in the module including the composite substrate on which the columnar or prismatic external connection terminals having a constant cross-sectional area are provided. Thus, stress applied to the external connection terminals 3, for example, due to a fall can be distributed, and sufficient connection strength is ensured between the ceramic substrate 1 and the external connection terminals 3. Further, since the sealing layer 4 is provided, the electronic components 2 mounted on the surface of the ceramic substrate 1 opposite to the surface on which the external connection terminals 3 are provided are protected, and the module 10 is prevented from warping.

### Second Preferred Embodiment

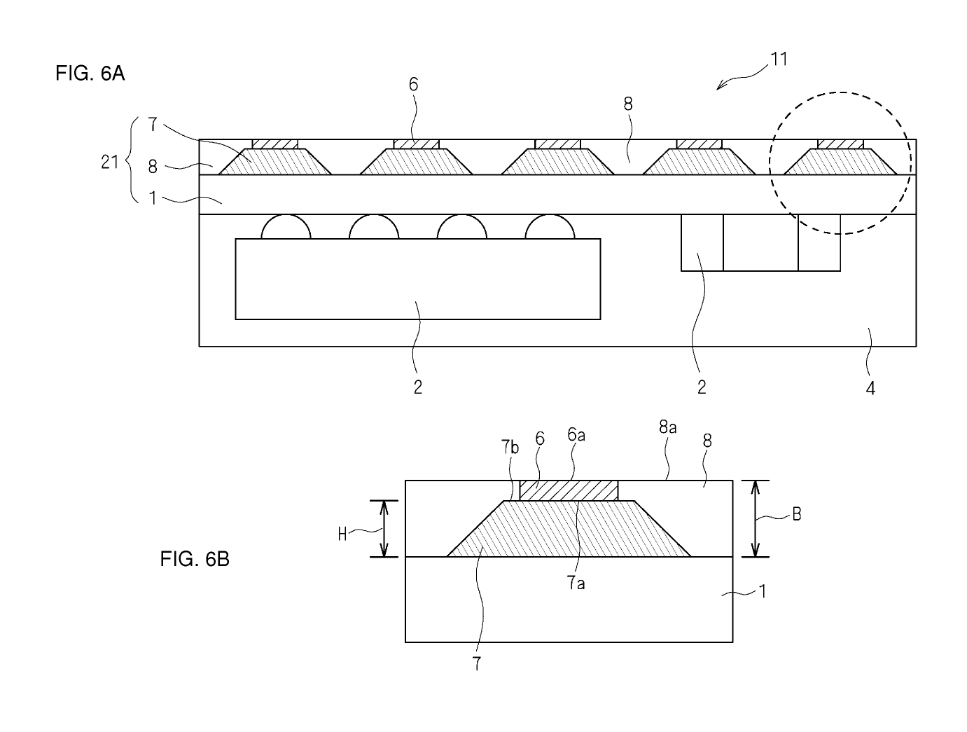

FIGS. 6A and 6B include schematic views illustrating a structure of a module according to a second preferred embodiment of the present invention. As illustrated in FIG. 6A, a module 11 preferably includes a ceramic substrate 1, a plurality of electronic components 2 mounted on both surfaces of the ceramic substrate 1 or a surface of the ceramic substrate 1 opposite to a surface on which external connection terminals 7 are provided, a plurality of substantially truncated pyramidal external connection terminals 7 provided on one surface of the ceramic substrate 1, a sealing layer 4 in which the electronic components 2 mounted on the surface of the ceramic substrate 1 opposite to the surface on which the external connection terminals 7 are provided are sealed with resin, and a resin layer 8 that covers the one surface of the ceramic substrate 1 on which the plurality of external connection terminals 7 are provided. The ceramic substrate 1, the external connection terminals 7, and the resin layer 8 define a composite substrate 21. The module 11 preferably has the same structure as that of the module 10 illustrated in FIG. 1 except that the height of the resin layer 8 is different. Constituent elements other than the external connection terminals 7 and the resin layer 8 are denoted by the same reference numerals, and detailed descriptions thereof are skipped.

FIG. 6B is an enlarged view of one external connection terminal 7 and its surroundings in an encircled portion of FIG. 6A. As illustrated in FIG. 6B, a height H of the external connection terminal 7 from one surface of the ceramic substrate 1 is preferably set to be less than a thickness B of the resin layer 8. A recess is provided on a surface 8a of the resin layer 8 opposite to a ceramic-substrate 1 side surface, and an end surface of the external connection terminal 7 opposite to an end surface connected to the ceramic substrate 1 is preferably partially or entirely exposed from the recess. For this reason, when a plated layer 6 is provided on the exposed end surface 7a of the external connection terminal 7, the plated layer 6 does not protrude from the surface 8a of the resin layer 8 opposite to the ceramic-substrate 1 side surface, and one surface of the composite substrate 21 where the external connection terminal 7 is provided can preferably be made flat or substantially flat. In particular, by arranging the plated layer 6 such that a surface 6a of the plated layer 6 provided on the exposed end surface 7a of the external connection terminal 7 is flush or substantially flush with the surface 8a of the resin layer 8 opposite to the ceramic-substrate 1 side surface, the one surface of the composite substrate 21 where the external connection terminal 7 is provided can be further flattened.

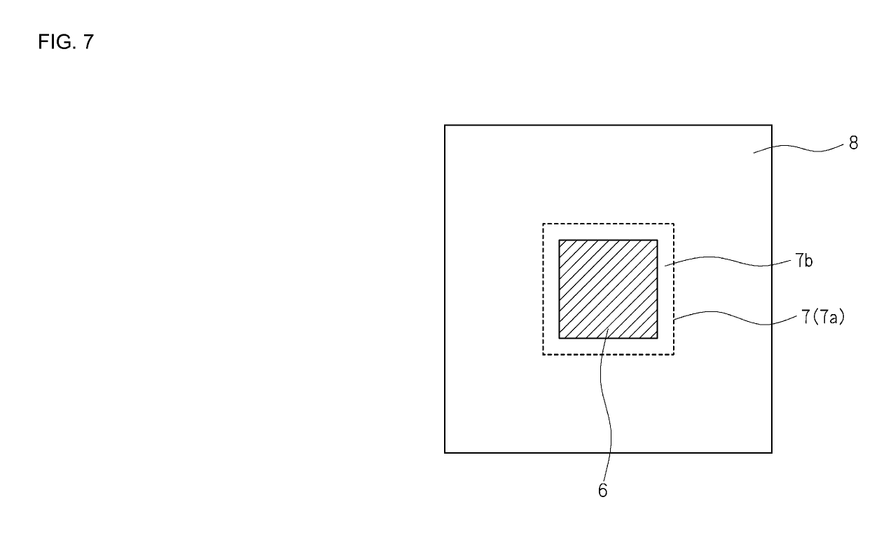

FIG. 7 is a plan view illustrating structures of one external connection terminal 7 and its surroundings in the module 11 according to the second preferred embodiment of the present invention. As illustrated in FIG. 7, the resin layer 8 is arranged to cover an outer peripheral edge of the exposed end surface 7a of the external connection terminal 7, and the exposed end surface 7a of the external connection terminal 7 has an area 7b overlapping with the resin layer 8 all around the outer peripheral edge (four sides). The plated layer 6 is provided on the exposed end surface 7a of the external connection terminal 7 except for the area 7b overlapping with the resin layer 8. Since the area 7b overlapping with the resin layer 8 is provided, even when the plated layer 6 is formed on the exposed end surface 7a of the external connection terminal 7 after the resin layer 8 is formed, the connection strength between the ceramic substrate 1 and the external connection terminal 7 is unlikely to be reduced, for example, by entry of plating solution into a boundary portion between the ceramic substrate 1 and the external connection terminal 7. The exposed end surface 7a of the external connection terminal 7 does not always need to have the area 7b overlapping with the resin layer 8 all around the outer peripheral edge (four sides), and it is satisfactory as long as the end surface 7a has the area 7b overlapping with the resin layer 8 at least in part (for example, on one side).

As described above, in the module 11 (composite substrate 21) according to the second preferred embodiment of the present invention, the height (H) of the external connection terminals 7 from one surface of the ceramic substrate 1 is preferably set to be less than the thickness (B) of the resin layer 8. Therefore, when the plated layers 6 are formed on the exposed end surfaces 7a of the external connection terminals 7, the plated layers 6 preferably do not protrude from the surface 8a of the resin layer 8 opposite to the ceramic-substrate 1 side surface, and one surface of the composite substrate 21 where the external connection terminal 7 are provided can be made flat or substantially flat. Even if the plated layers 6 are thick and protrude from the surface 8a of the resin layer 8 opposite to the ceramic-substrate 1 side surface, the height of the portions protruding from the resin layer 8 can be reduced by adjusting the height of the external connection terminals 7.

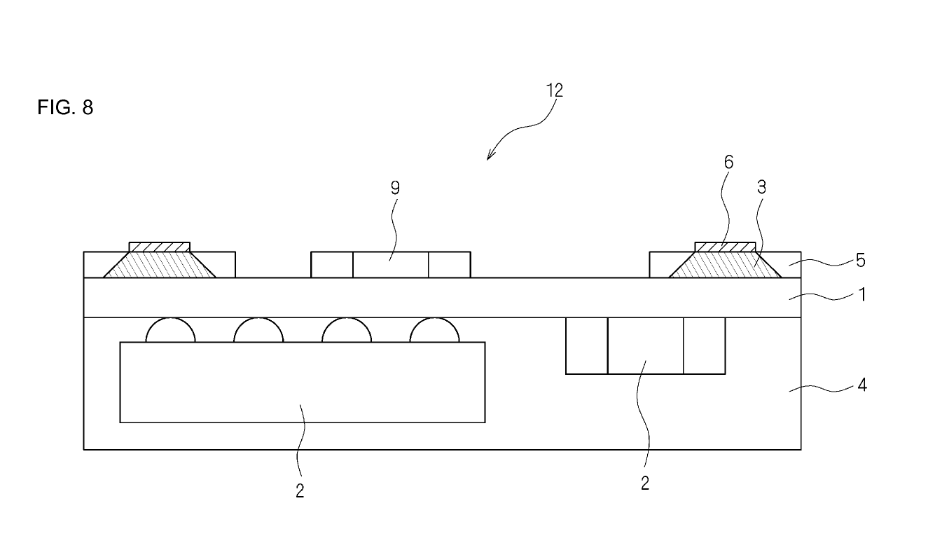

In the modules 10 and 11 (composite substrates 20 and 21) according to the first and second preferred embodiments of the present invention, a plurality of external connection terminals 3 and 7 preferably are arranged in a lattice configuration on one surface of the ceramic substrate 1. However, the external connection terminals 3 and 7 do not always need to be arranged in a lattice configuration, and may be arranged in other manners if so desired. Further, electronic components may be mounted on a portion of the one surface of the ceramic substrate where the external connection terminals are not provided. FIG. 8 is a schematic view illustrating a structure of a module in which electronic components are mounted on a portion of one surface of a ceramic substrate 1 where external connection terminals 3 are not provided. As illustrated in FIG. 8, a module 12 includes a plurality of external connection terminals 3 provided in a peripheral edge portion of one surface of a ceramic substrate 1, a resin layer 5 provided on the one surface of the ceramic substrate 1, an electronic component 9 mounted on a portion of the one surface of the ceramic substrate 1 where the external connection terminals 3 are not provided, electronic components 2 mounted on the other surface of the ceramic substrate 1 where the external connection terminals 3 are not provided, and a sealing layer 4 in which the other surface of the ceramic substrate 1 with the electronic components 2 mounted thereon is sealed with resin. That is, the module 12 may have a structure in which the electronic components 2 and 9 are mounted on both surfaces of the ceramic substrate 1.

While preferred embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. A composite substrate comprising:
a ceramic substrate including, on at least one surface, a circuit wire on which an electronic component is to be mounted;
a plurality of external connection terminals provided on one surface of the ceramic substrate; and
a resin layer provided on the one surface of the ceramic substrate; wherein
the plurality of external connection terminals have a cross-sectional area that decreases with increasing distance from the one surface of the ceramic substrate, and end surfaces of the plurality of external connection terminals opposite to end surfaces connected to the ceramic substrate are partially or entirely exposed from the resin layer.

2. The composite substrate according to claim 1, wherein a height of the plurality of external connection terminals from the one surface of the ceramic substrate is less than a thickness of the resin layer.

3. The composite substrate according to claim 2, wherein outer peripheral edges of the end surfaces of the plurality of external connection terminals opposite to the end surfaces connected to the ceramic substrate are covered with the resin layer.

4. The composite substrate according to claim 1, wherein plated layers are provided on the end surfaces of the plurality of external connection terminals exposed from the resin layer.

5. The composite substrate according to claim 4, wherein the plated layers are arranged so as not to protrude from the resin layer.

6. The composite substrate according to claim 1, wherein the plurality of external connection terminals are arranged in a lattice configuration on the one surface of the ceramic substrate.

7. A module comprising:
the composite substrate according to claim 1; and
at least one electronic component mounted on both surfaces of the ceramic substrate or a surface opposite to the surface on which the plurality of external connection terminals are provided.

8. The module according to claim 7, further comprising a sealing layer in which the at least one electronic component mounted on the surface opposite to the surface on which the plurality of external connection terminals are provided is sealed with resin.

9. A composite-substrate production method comprising:
a first step of forming, in a resin sheet, a plurality of holes whose aperture area is smaller on one side than on the other side and filling the plurality of holes with a conductive material;
a second step of stacking a plurality of the resin sheets on one surface of an unfired ceramic substrate including, on at least one surface, a circuit wire on which an electronic component is to be mounted so that the aperture area of the holes successively decreases, and firing the plurality of resin sheets to form a plurality of external connection terminals having a cross-sectional area that decreases with increasing distance from the one surface of the fired ceramic substrate; and
a third step of forming a resin layer on the one surface of the ceramic substrate so that end surfaces of the plurality of external connection terminals opposite to end surfaces connected to the ceramic substrate are exposed partially or entirely.

10. A composite-substrate production method comprising:
a first step of screen-printing a conductive material a plurality of times on one surface of an unfired ceramic substrate including, on at least one surface, a circuit wire on which an electronic component is to be mounted so as to form a plurality of unfired external connection terminals having a shape whose cross-sectional area decreases with increasing distance from the one surface of the ceramic substrate;
a second step of firing the ceramic substrate on which the plurality of unfired external connection terminals are formed; and
a third step of forming a resin layer on the one surface of the ceramic substrate so that end surfaces of the plurality of external connection terminals opposite to end surfaces connected to the ceramic substrate are exposed partially or entirely.

11. A composite-substrate production method comprising:
a first step of forming, in an unfired ceramic sheet, a plurality of holes whose aperture area is smaller on one side than on the other side and filling the plurality of holes with a conductive material;
a second step of stacking a plurality of the ceramic sheets on one surface of an unfired ceramic substrate having a sintering temperature lower than that of the ceramic sheets and including, on at least one surface, a circuit wire on which an electronic component is to be mounted so that the aperture area of the holes successively decreases, firing the plurality of ceramic sheets, and removing the unsintered ceramic sheets to form a plurality of external connection terminals having a shape whose cross-sectional area decreases with increasing distance from the one surface of the ceramic substrate; and
a third step of forming a resin layer on the one surface of the ceramic substrate so that end surfaces of the plurality of external connection terminals opposite to end surfaces connected to the ceramic substrate are exposed partially or entirely.

12. The composite-substrate production method according to claim 9, wherein the ceramic substrate is a ceramic multilayer substrate formed by stacking a plurality of ceramic layers.

13. The composite-substrate production method according to claim 9, wherein, in the third step, the end surfaces of the plurality of external connection terminals opposite to the end surfaces connected to the ceramic substrate are partially or entirely exposed by grinding a surface of the resin layer.

14. The composite-substrate production method according to claim 9, wherein, in the third step, the resin layer is formed so that a thickness of the resin layer is more than a height of the plurality of external connection terminals from the one surface of the ceramic substrate.

15. The composite-substrate production method according to claim 14, wherein, in the third step, the resin layer is formed to cover outer peripheral edges of the end surfaces of the plurality of external connection terminals opposite to the end surfaces connected to the ceramic substrate.

16. The composite-substrate production method according to claim 9, wherein, in the third step, plated layers are formed on the end surfaces of the plurality of external connection terminals exposed from the resin layer so as not to protrude from the resin layer.

17. The composite substrate according to claim 1, wherein the one surface on which the plurality of external connection terminals are provided is flat or substantially flat.

18. The composite-substrate production method according to claim 9, wherein the one surface on which the plurality of external connection terminals are provided is flat or substantially flat.

19. The composite-substrate production method according to claim 10, wherein the one surface on which the plurality of external connection terminals are provided is flat or substantially flat.

20. The composite-substrate production method according to claim 11, wherein the one surface on which the plurality of external connection terminals are provided is flat or substantially flat.
